(19) United States
(12) Patent Application Publication
(10) Pub. No.: US 2007/0278500 A1
(43) Pub. Date: Dec. 6, 2007

(54) Package module of light emitting diode

(75) Inventor: Feng-Li Lin, Taishan Township (TW)

Correspondence Address: BIRCH STEWART KOLASCH & BIRCH, PO BOX 747, FALLS CHURCH, VA, 22040-0747, US

(73) Assignee: GIGNO TECHNOLOGY CO., LTD.

(21) Appl. No.: 11/790,243

(22) Filed: Apr. 24, 2007

(30) Foreign Application Priority Data
Apr. 25, 2006 (TW) 095114747

(51) Int. Cl. H01L 33/00; H01L 31/12

(52) U.S. Cl. 257/81; 257/99; 257/E33.005; 257/E31.095

(57) ABSTRACT

A package module of a light emitting diode includes a substrate, a first light emitting diode and a transistor. The first light emitting diode is disposed on the substrate, and the transistor is electrically connected with the first light emitting diode. The transistor is disposed on the substrate and turns on or off the first light emitting diode. The first light emitting diode and the transistor are disposed in a same package.

### CROSS REFERENCE TO RELATED APPLICATIONS

This Non-provisional application claims priority under 35 U.S.C. §119(a) on Patent Application No(s). 095114747 filed in Taiwan, Republic of China on Apr. 25, 2006, the entire contents of which are hereby incorporated by reference.

### BACKGROUND OF THE INVENTION

1. Field of Invention

The invention relates to a package module of a diode, and, in particular, to a package module of a light emitting diode.

2. Related Art

With the high development of the technology, light emitting diodes (LEDs) having the advantages of the lightness, the power-saving property and the long lifetime have been currently and widely applied to indicators and displays of information, communication and consumer electronic products, such as an indicator lamp, a portable flashlight, a liquid crystal display (LCD) backlight plate, a floor lamp, an emergency lamp, a medical apparatus light source, auxiliary illumination, main illumination, and the like. So, the LED is one of the important electronic devices. At present, the application of the white LED is also developed, and has entered another ambit from the small illumination market. Also, the white LED is further applied to a backlight source of a LCD and tends to replace the conventional cold cathode fluorescent lamp gradually.

Referring to FIGS. 1 and 2, a conventional backlight module 1 having light emitting diodes serving as light sources includes a housing 11, a plurality of package modules 12 of the light emitting diodes, a carrier 13, a driving circuit board 14 and at least one optical film 15.

Each package module 12 has a plurality of LED devices 121 and a printed circuit board 122. Each LED device 121 is disposed on the printed circuit board 122, and then each package module 12 is fixed to the carrier 13, which is screwed to the housing 11 (not shown). The driving circuit board 14 drives the package module 12 and mainly has a driving loop including an active device and a passive device. The driving circuit board 14 is fixed to the carrier 13 and is thus disposed opposite to the package module 12. Devices, such as transistors 141, for driving and controlling the light emitting intensity of the package module 12 are disposed on the driving circuit board 14.

However, each of the LED devices 121 of each package module 12 is usually packaged first and then disposed on the printed circuit board 122. In addition, the devices, such as the transistors 141, on the driving circuit board 14 cannot be disposed on the driving circuit board 14 until they are packaged. Consequently, the cost of packaging the devices one by one becomes high and is thus wasted.

Therefore, it is an important subject to provide a package module of a light emitting diode that can solve the above mentioned problems.

### SUMMARY OF THE INVENTION

In view of the foregoing, the invention is to provide a package module of a light emitting diode, in which the light emitting diode and a transistor may be packaged in the same package so that the cost of the packaging process may be reduced.

In addition, the invention is to provide a package module of a light emitting diode, in which any two of the light emitting diode, a transistor and a photosensor may be packaged in the same package so that the cost of the packaging process may be reduced.

To achieve the above, the invention discloses a package module including a substrate, a first light emitting diode and a transistor. The first light emitting diode and the transistor are disposed on the substrate. The transistor is electrically connected with the first light emitting diode to turn on or off the first light emitting diode. The first light emitting diode and the transistor are disposed in a same package.

To achieve the above, the invention also discloses a package module including a substrate, a first light emitting diode, a photosensor and a transistor. The first light emitting diode, the photosensor and the transistor are disposed on the substrate. The transistor is electrically connected with the first light emitting diode and turns on or off the first light emitting diode. Any two of the first light emitting diode, the photosensor and the transistor are disposed in a same package.

As mentioned above, the first LED and the transistor are disposed on the substrate, and the first LED and the transistor are disposed in the same package in the package module of the LED according to the invention. Compared with the prior art, the cost of the packaging process may be reduced by disposing the first LED and the transistor in the same package. In addition, when the second LED is driven by the reverse bias in the embodiment of the invention, the photosensor for sensing the light emitting intensity is formed. Thus, the intensity of the LED may be adjusted according to the feedback, and it is possible to eliminate the additional photosensor for sensing the light intensity.

### BRIEF DESCRIPTION OF THE DRAWINGS

The invention will become more fully understood from the detailed description given herein below illustration only, and thus is not limitative of the present invention, and wherein:

FIG. 1 shows a conventional backlight module having a light emitting diode serving as a light source;

FIG. 2 is a cross-sectional view showing the light emitting diode of FIG. 1;

FIG. 3 is a pictorial view showing a package module of a light emitting diode according to a preferred embodiment of the invention;

FIG. 4 is a cross-sectional view showing the package module of the light emitting diode according to the preferred embodiment of the invention;

FIG. 5 is a schematic illustration showing the package module of the light emitting diode according to the preferred embodiment of the invention, wherein the first light emitting diode, the transistor and the driving control loop are disposed in the same package;

FIG. 6 is a schematic illustration showing the package module of the light emitting diode having a photosensor disposed in the package according to the preferred embodiment of the invention;

FIG. 7 is a schematic illustration showing the package module of the light emitting diode having the photosensor outside the package according to the preferred embodiment of the invention;

FIG. 8 is a schematic illustration showing the package module of the light emitting diode having a transparent cover according to the preferred embodiment of the invention;

FIG. 9 is a schematic illustration showing the package module of the light emitting diode according to the preferred embodiment of the invention, wherein the first light emitting diode, the transistor, the photosensor, the memory and the driving control loop are disposed in the same package;

FIG. 10 is a schematic illustration showing the package module of the light emitting diode according to the preferred embodiment of the invention, wherein the first light emitting diode, the second light emitting diode, the transistor and the driving control loop are disposed in the same package;

FIG. 11 is a schematic illustration showing the package module of the light emitting diode according to the preferred embodiment of the invention, wherein the first light emitting diode, the second light emitting diode, the light emitting diodes, the transistor and the driving control loop are disposed in the same package; and

FIG. 12 is a schematic illustration showing a package module of a light emitting diode according to another preferred embodiment of the invention, wherein the first light emitting diode and the transistor are disposed in the same package, and the photosensor is disposed in the other package.

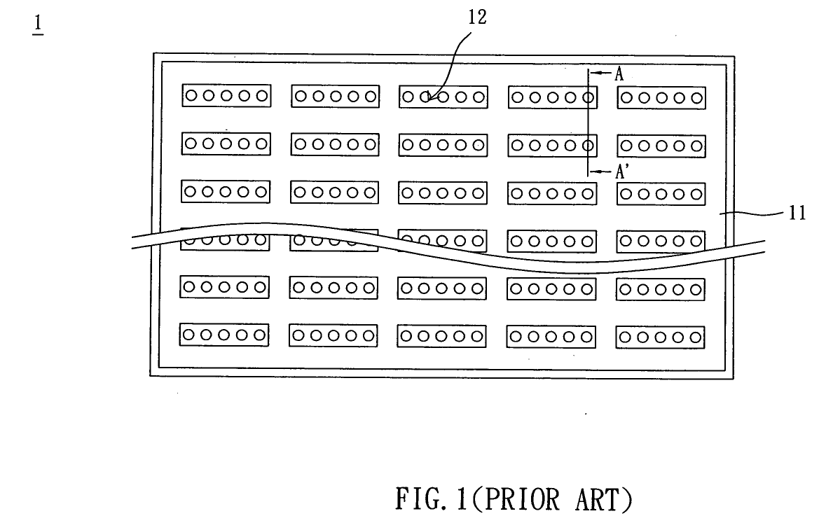

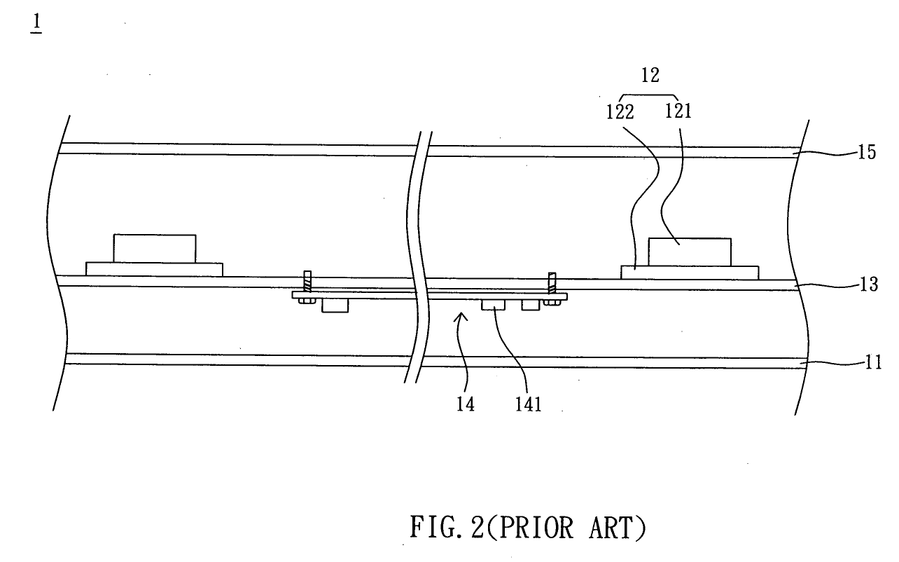

### DETAILED DESCRIPTION OF THE INVENTION

The present invention will be apparent from the following detailed description, which proceeds with reference to the accompanying drawings, wherein the same references relate to the same elements.

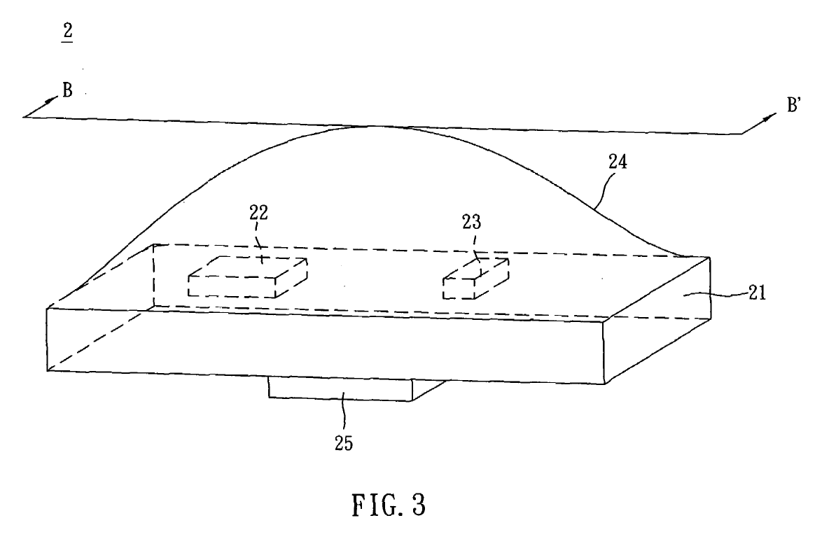

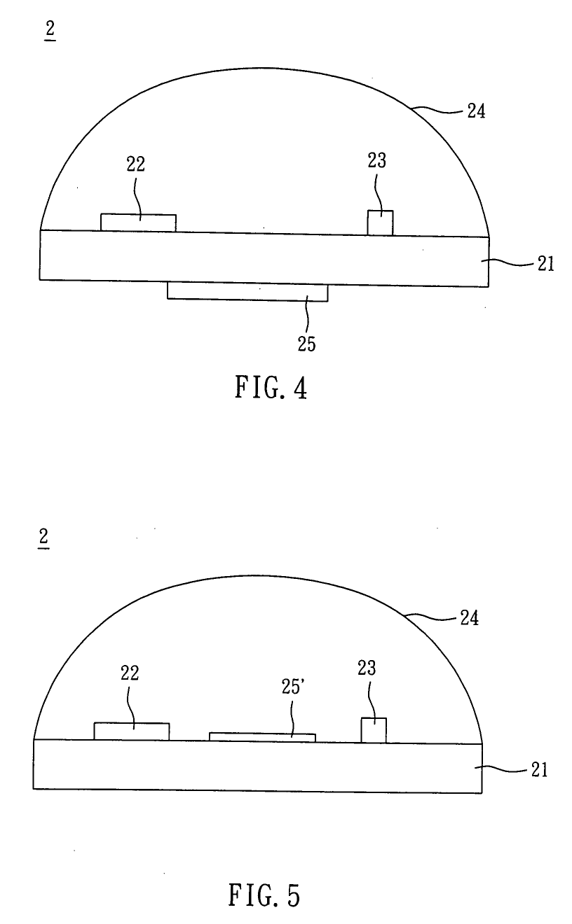

Referring to FIGS. 3 and 4, a package module 2 of a light emitting diode (LED) according to this embodiment of the invention includes a substrate 21, a first LED 22 and a transistor 23, wherein the first LED 22 and the transistor 23 are disposed in the same package 24.

In this embodiment, the substrate 21 is not particularly restricted and may be a printed circuit board, a heat dissipating plate or a glass substrate. The material of the package 24 is not particularly restricted and may be a transparent resin, such as a transparent epoxy resin, or a transparent glue, such as silicone.

As shown in FIG. 4, the first LED 22 of this embodiment may be a LED chip or a LED die (bare chip or die) directly disposed on the substrate 21.

The transistor 23, which is electrically connected with the first LED 22 and disposed on the substrate 21, turns on or off the first LED 22. The transistor 23 may be a switching device, such as a bipolar transistor (BJT), a field effect transistor (FET) or a metal oxidation semiconductor transistor (MOSFET).

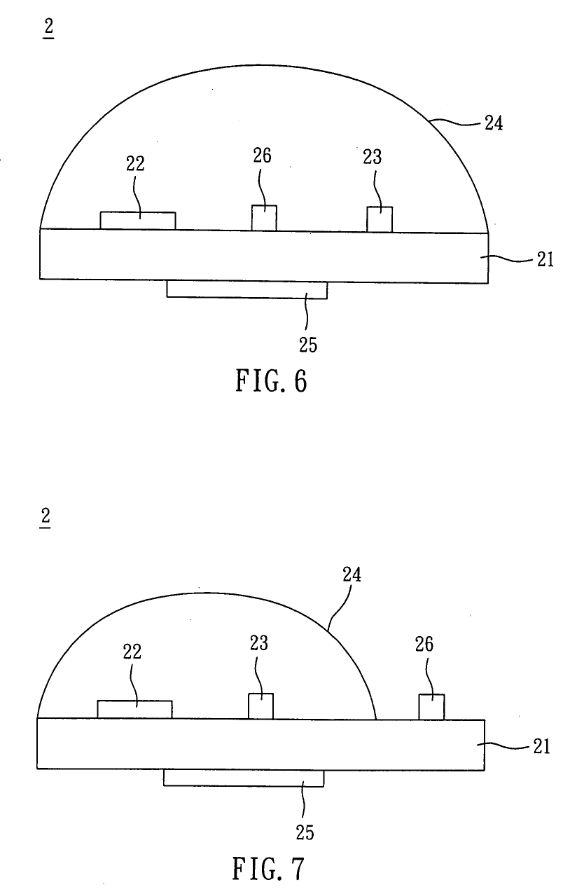

Referring to FIG. 4, the package module 2 of the LED further includes a driving control loop 25, which is electrically connected with the first LED 22 and the transistor 23 and outputs a pulse width modulation (PWM) signal to the transistor 23 through the driving control loop 25 so that the transistor 23 turns on or off according to the pulse width modulation signal and thus controls the duty cycle of the first LED 22. In addition, it is also possible to output a DC signal to the first LED 22 through the driving control loop 25 and control the light emitting intensity of the first LED 22 by adjusting the level of the DC signal. The driving control loop 25 of this embodiment may be fixed to the other side of the substrate 21 and disposed opposite to and electrically connected with the first LED 22 and the transistor 23. In addition, when the driving control loop 25 is integrated into a chip 25′, the chip 25′ may be disposed in the package 24, as shown in FIG. 5. Referring to FIGS. 6 and 7, the package module 2 may further include a photosensor 26, which may be disposed in the package 24, as shown in FIG. 6, or may be disposed on the substrate 21 but outside the package 24, as shown in FIG. 7. In this embodiment, when the photosensor 26 is disposed in the package 24 and the package 24 is opaque, the light emitting intensities of the first LED 22 and other LEDs (not shown) in the package 24 may be sensed simultaneously or individually. When the photosensor 26 is disposed outside the package, the light emitting intensities of the first LEDs 22 in the neighboring packages 24 or the LEDs (not shown) in other package modules 2 may be sensed simultaneously or individually.

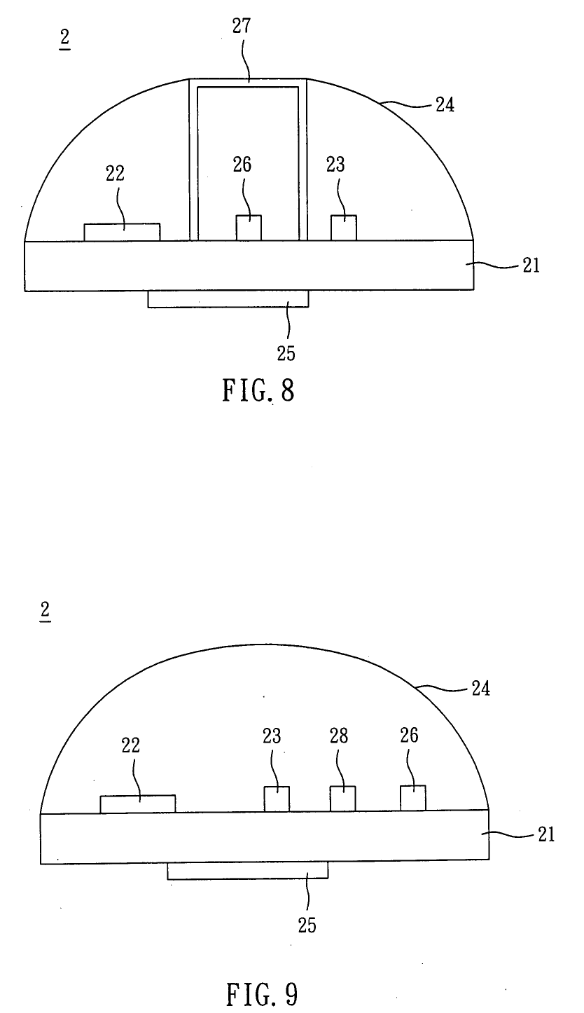

Referring to FIG. 8, the package module 2 of this embodiment further includes a transparent cover 27 covering the photosensor 26 to form a transparent window, through which the photosensor 26 senses the light emitting intensities of other LEDs disposed in the backlight module. In addition, when the package 24 is made of a transparent material, the photosensor 26 can sense the light emitting intensity (not shown) of the LED without passing through the transparent cover 27.

Referring to FIG. 9, the package module 2 of this embodiment further includes a memory 28, which is disposed on the substrate 21 and electrically connected with the driving control loop 25. The memory 28 may be disposed in, without limitation to, the package 24, or disposed on the other side of the substrate 21 and disposed opposite to the first LED 22 (not shown). The memory 28 of this embodiment is, for example, a non-volatile memory for storing a look up table recording the relationship between a plurality of sets of light emitting intensities and the current data. The driving control loop 25 may look up the look up table in the memory 28 to find the reference data for controlling the light emitting intensity of the first LED 22.

The operation of the package module 2 of this embodiment will be described with reference to FIG. 9. After the photosensor 26 senses the light emitting intensity of the first LED 22, the photosensor 26 converts the sensed light emitting intensity into a current, and transfers the current to the driving control loop 25. The driving control loop 25 searches for, from the memory 28, the reference value of the light emitting intensity corresponding to the current according to the received current so as to adjust the light emitting intensity of the first LED 22 to the reference value.

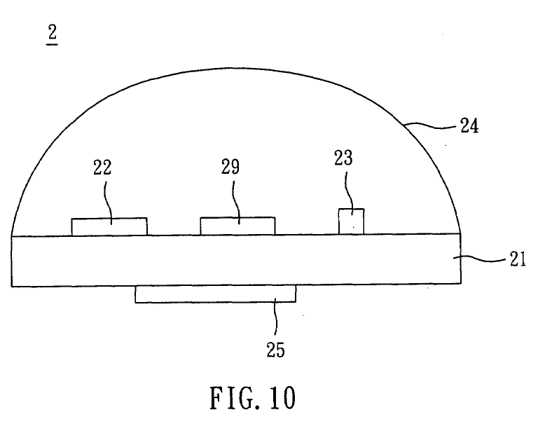

Referring to FIG. 10, the package module 2 of this embodiment further includes a second LED 29, which is electrically connected with the first LED 22 and disposed on the substrate 21. The second LED 29 is also disposed in the package 24 and may drive and control the light emitting intensity of the second LED 29 through the same driving control loop 25. In this embodiment, the connection between the first LED 22 and the second LED 29 is not particularly restricted. Thus, the first LED 22 and the second LED 29 may be connected in series or in parallel, and may be driven by the DC power or the AC power. In addition, when the first LED 22 and the second LED 29 are connected in parallel and reversely, the inputted AC power may drive the first LED 22 and the second LED 29 to emit light alternately, and the inputted DC power may drive one of the LEDs to emit light, and reversely bias the other of the LEDs to form the photosensor 26 for sensing the ambient light intensity (not shown).

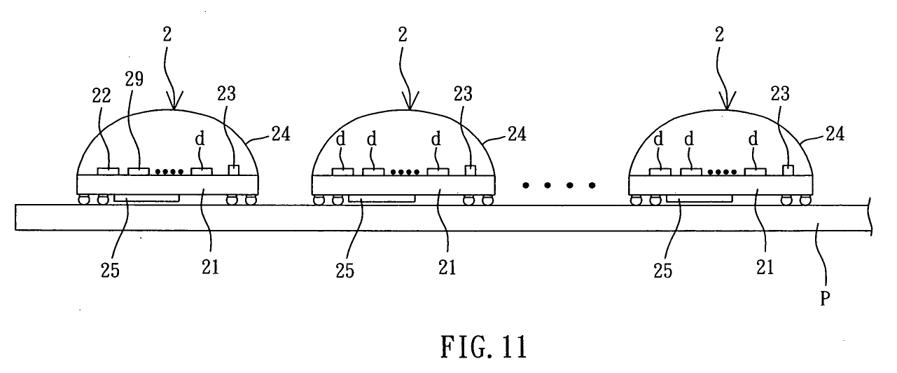

According to the package module 2 of this embodiment, as shown in FIG. 11, the first LED 22 and the second LED 29 may be packaged in the same package 24, and a plurality of LEDs d may be packaged in the same package 24. The transistor 23 turns on and off the first LED 22, the second LED 29 and each LED d, and the driving control loop 25 drives and controls the light emitting intensity of each of the first LED 22, the second LED 29 and the LEDs d. In this embodiment, a plurality of package modules 2 may be disposed on a fixing plate P in a flip chip manner or may be disposed on the fixing plate P by way of surface mounting. The fixing plate P may be, without limitation to, a housing of a backlight module, a heat sink or a printed circuit board.

In the package module 2, the first LED 22, the second LED 29, the transistor 23, the photosensor 26 and the driving control loop 25 are disposed on the same substrate 21, and the above-mentioned components and the plurality of LEDs d may be packaged in the same package 24. In this manner, the cost of the packaging process may be reduced. In addition, when the second LED 29 is driven by the backward bias, it can function as a photosensor to sense the light emitting intensities of other LEDs, so that the number of photosensors 26 may be reduced.

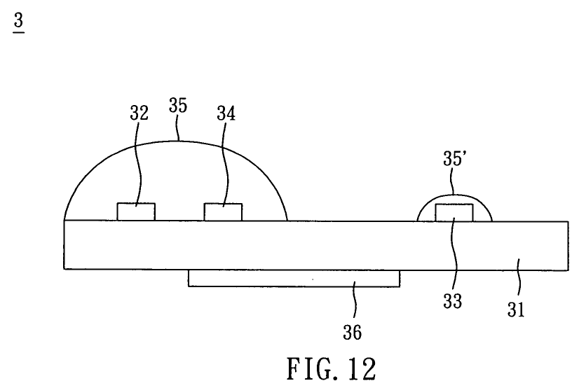

Referring to FIG. 12, a package module 3 according to another preferred embodiment of the invention includes a substrate 31, a first LED 32, a transistor 33 and a photosensor 34. The first LED 32 is disposed on the substrate 31, the photosensor 34 is disposed on the substrate 31, and the transistor 33 is electrically connected with the first LED 32 and disposed on the substrate 31 to turn on or off the first LED 32. Any two of the first LED 32, the photosensor 34 and the transistor 33 are disposed in the same package 35. Herein, the first LED 32 and the photosensor 34 are disposed in the same package 35, and the transistor 33 is disposed in the other package 35′.

The structures, functions and operations of the first LED 32, the transistor 33, the photosensor 34, the driving loop 36 and the packages 35 and 35′ according to this embodiment are the same as those of the first LED 22, the photosensor 26, the transistor 23, the driving loop 25 and the package 24 according to the above-mentioned preferred embodiment (FIGS. 3 and 4), so detailed descriptions thereof will be omitted.

In summary, the first LED and the transistor are disposed on the substrate, and the first LED and the transistor are disposed in the same package in the package module of the LED according to the invention. Compared with the prior art, the cost of the packaging process may be reduced by disposing the first LED and the transistor in the same package. In addition, when the second LED is driven by the reverse bias in the embodiment of the invention, the photosensor for sensing the light emitting intensity is formed. Thus, the intensity of the LED may be adjusted according to the feedback, and it is possible to eliminate the additional photosensor for sensing the light intensity.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A package module, comprising:
a substrate;
a first light emitting diode disposed on the substrate; and
a transistor, which is electrically connected with the first light emitting diode and disposed on the substrate to turn on or off the first light emitting diode, wherein the first light emitting diode and the transistor are disposed in a same package.

2. The package module according to claim 1, wherein the substrate is a printed circuit board, a heat dissipating plate or a glass substrate, and the first light emitting diode is a light emitting diode chip or a light emitting diode die.

3. The package module according to claim 1, further comprising a photosensor disposed in the package.

4. The package module according to claim 3, further comprising:
a transparent cover for covering the photosensor.

5. The package module according to claim 1, further comprising a driving control loop, which is electrically connected with the first light emitting diode and the transistor, and controls a light emitting intensity of the first light emitting diode.

6. The package module according to claim 5, wherein the driving control loop is disposed in the package.

7. The package module according to claim 5, further comprising a memory, which is disposed on the substrate and electrically connected with the driving control loop.

8. The package module according to claim 1, further comprising a second light emitting diode, which is electrically connected with the first light emitting diode and disposed on the substrate.

9. The package module according to claim 8, wherein the second light emitting diode is disposed in the package.

10. The package module according to claim 8, wherein the second light emitting diode is driven by a backward bias to form a photosensor.

11. The package module according to claim 8, wherein the second light emitting diode and the first light emitting diode are connected in series.

12. The package module according to claim 8, wherein the second light emitting diode and the first light emitting diode are connected in parallel and reversely.

13. A package module, comprising:
a substrate;
a first light emitting diode disposed on the substrate;
a photosensor disposed on the substrate; and
a transistor, which is electrically connected with the first light emitting diode and disposed on the substrate, and turns on or off the first light emitting diode, wherein any two of the first light emitting diode, the photosensor and the transistor are disposed in a same package.

14. The package module according to claim 13, wherein the substrate is a printed circuit board, a heat dissipating plate or a glass substrate, and the first light emitting diode is a light emitting diode chip or a light emitting diode die.

15. The package module according to claim 13, further comprising:
a transparent cover for covering the photosensor.

16. The package module according to claim 13, further comprising a driving control loop, which is electrically connected with the first light emitting diode, the photosensor and the transistor.

17. The package module according to claim 16, wherein the driving control loop is disposed in the package.

18. The package module according to claim 16, further comprising a memory, which is disposed on the substrate and electrically connected with the driving control loop.

19. The package module according to claim 13, further comprising a second light emitting diode, which is electrically connected with the first light emitting diode and disposed on the substrate.

20. The package module according to claim 19, wherein the second light emitting diode is disposed in the package.

21. The package module according to claim 19, wherein the second light emitting diode is driven by a backward bias to form a photosensor.

22. The package module according to claim 19, wherein the second light emitting diode and the first light emitting diode are connected in series.

23. The package module according to claim 19, wherein the second light emitting diode and the first light emitting diode are connected in parallel and reversely.
